(19) United States
(12) Patent Application Publication
(10) Pub. No.: US 2026/0123223 A1
(43) Pub. Date: Apr. 30, 2026

(54) DISPLAY DEVICE

(71) Applicant: LG Display Co., Ltd., Seoul (KR)

(72) Inventors: Taehwi Kim, Paju-si (KR); SeHwan Na, Paju-si (KR); Soonsung Ahn, Paju-si (KR)

(73) Assignee: LG Display Co., Ltd., Seoul (KR)

(21) Appl. No.: 19/336,113

(22) Filed: Sep. 22, 2025

(30) Foreign Application Priority Data
Oct. 29, 2024 (KR) 10-2024-0150014

(51) Int. Cl. H10K 59/131; H10H 29/30; H10H 29/49; H10K 59/35; H10K 59/65

(52) U.S. Cl. CPC H10K 59/1315; H10H 29/352; H10H 29/49; H10K 59/352; H10K 59/65

(57) ABSTRACT

A display device is provided, which is capable of minimizing luminance variation caused by differences in wiring resistance within an optical area by differentially arranging a plurality of data connection lines. The data connection lines can include a first connection line and a second connection line having a lower resistance than the first connection line, in the optical area.

### CROSS-REFERENCE TO RELATED APPLICATION

This application claims priority to Korean Patent Application No. 10-2024-0150014, filed in the Republic of Korea on Oct. 29, 2024, which is hereby expressly incorporated by reference for all purposes as if fully set forth herein.

### BACKGROUND

### Field

The present disclosure relates to a display device.

### Discussion of the Related Art

With advancements in technology, display devices can provide not only image display functions but also camera functions and various sensing capabilities. To achieve this, display devices are equipped with optoelectronic devices such as cameras and sensing sensors (also referred to as light-receiving devices or sensors).

Since optoelectronic devices need to receive light from the front of the display device, they must be installed in locations that facilitate light reception. Accordingly, conventional designs have placed cameras (camera lenses) and sensing sensors to be exposed on the front of the display device. As a result, the bezel of the display panel becomes wider, or optoelectronic devices are positioned in areas where a notch or a physical hole is formed within the display area of the display panel.

In other words, as optoelectronic devices such as cameras and sensing sensors, which receive light from the front to perform their designated functions, are incorporated into display devices, the bezel on the front of the display device can become larger, or design constraints can arise for the front of the display device. Additionally, when a display device includes optoelectronic devices, the structural configuration accommodating these devices can lead to unintended degradation in image quality.

### SUMMARY OF THE DISCLOSURE

The embodiments of the present disclosure can provide a display device in which an optoelectronic device is not exposed on the front of the display device, while still allowing the optoelectronic device, disposed below the display panel, to properly receive light through a light-transmitting structure.

The embodiments of the present disclosure can provide a display device that enables a high transmittance optical area through differential design of data connection lines while minimizing luminance variation caused by differences in line resistance within the optical area.

The embodiments of the present disclosure can provide a display device that ensures luminance uniformity through differential design of data connection lines, thereby improving optical characteristics and yield while enabling low-power operation.

The embodiments of the present disclosure can provide a display device that minimizes luminance variation by optimizing the design of the material, thickness, and wiring length of data connection lines.

The embodiments of the present disclosure can provide a display device comprising a display panel comprising an optical area having a plurality of transmissive areas and a plurality of first emission areas, a general area disposed outside the optical area and having a plurality of second emission areas, and a plurality of data connection lines disposed in a first direction in at least one of the plurality of transmissive areas; and an optoelectronic device disposed below the display panel and overlapping the optical area. The plurality of data connection lines includes at least one first connection line disposed in a first area and a second area of the optical area, and at least one second connection line disposed in the first area and having a lower resistance than the first connection line.

The embodiments of the present disclosure can provide a display device comprising a substrate including a plurality of transmissive areas and a plurality of emission areas; a transistor layer disposed on the substrate and including at least one transistor and a plurality of interlayer insulating films; a plurality of planarization layers disposed on the transistor layer; and a light-emitting device layer including a plurality of data sub-lines, which are disposed on any one of the plurality of planarization layers in the plurality of emission areas and electrically connected to at least one of a first connection line and at least one of a second connection line, and a plurality of light-emitting devices, which are disposed on the plurality of planarization layers and correspond to each of the plurality of emission areas.

According to the embodiments of the present disclosure, a display device can be provided in which an optoelectronic device is not exposed on the front of the display device, while still allowing the optoelectronic device, disposed below the display panel, to properly receive light through a light-transmitting structure.

According to the embodiments of the present disclosure, a display device can be provided that enables a high transmittance optical area through differential design of data connection lines while minimizing luminance variation caused by differences in line resistance within the optical area.

According to the embodiments of the present disclosure, a display device can be provided that ensures luminance uniformity through differential design of data connection lines, thereby improving optical characteristics and yield while enabling low-power operation.

According to the embodiments of the present disclosure, a display device can be provided that minimizes luminance variation by optimizing the design of the material, thickness, and wiring length of data connection lines.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1A to FIG. 1E are diagrams for illustrating a display device according to embodiments of the present disclosure.

FIG. 2 is a diagram for illustrating a system configuration of a display device according to embodiments of the present disclosure.

FIG. 3 is a diagram for illustrating an example of a sub-pixel according to embodiments of the present disclosure.

FIG. 4 is a diagram for illustrating an arrangement of sub-pixels in a general area and an optical area according to embodiments of the present disclosure.

FIG. 5A and FIG. 5B are diagrams for illustrating an arrangement of signal lines in a display panel according to embodiments of the present disclosure.

FIG. 6 and FIG. 7 are diagrams for illustrating an optical area according to embodiments of the present disclosure.

FIG. 8 to FIG. 13 are diagrams for illustrating various combinations of a first connection line and a second connection line in a display device, according to embodiments of the present disclosure.

FIG. 14 to FIG. 18 are diagrams for illustrating implementation examples of a display device according to embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately”is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure will be described in detail with reference to the accompanying drawings. All the components of each display device/apparatus according to all embodiments of the present disclosure are operatively coupled and configured.

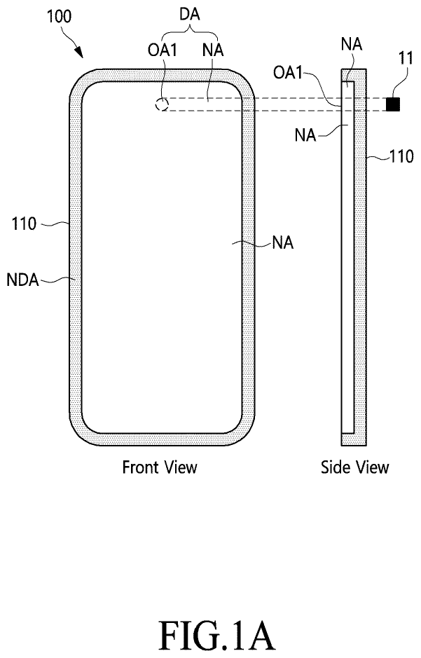

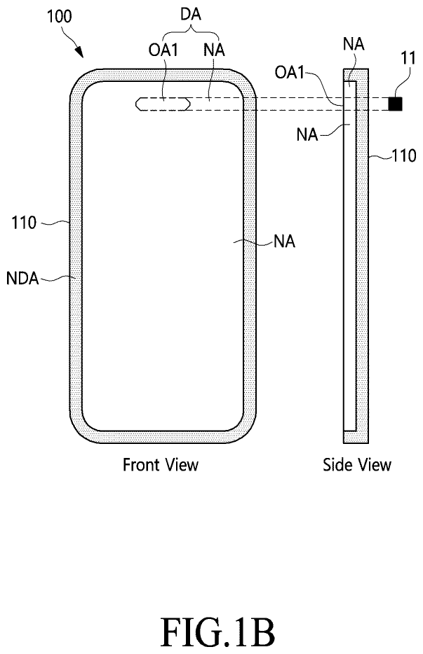

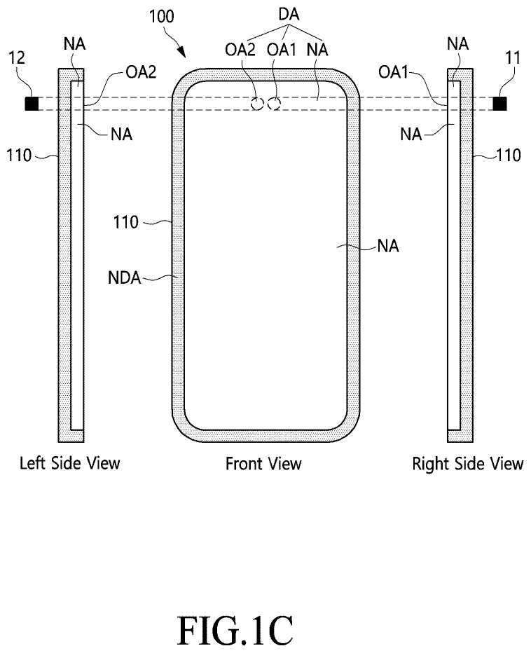

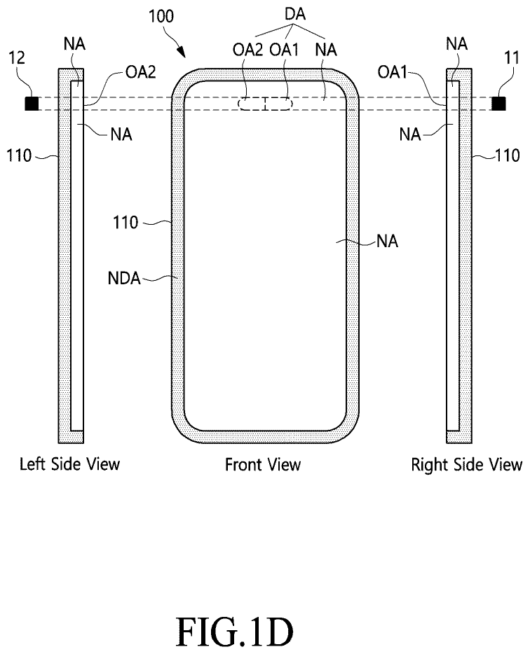

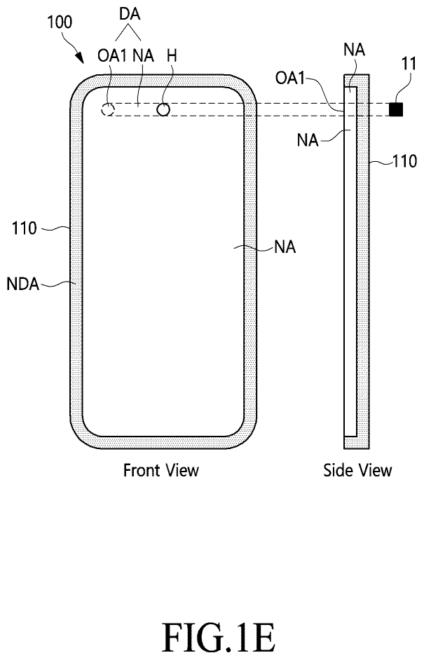

FIG. 1A to FIG. 1E are diagrams for illustrating a display device 100 according to embodiments of the present disclosure.

Referring to FIG. 1A to FIG. 1E, the display device 100 according to embodiments of the present disclosure can include a display panel 110 for displaying an image and at least one optoelectronic device 11 and/or 12.

The display panel 110 can include a display area DA (or active area) where an image is displayed and a non-display area NDA (or non-active area) where an image is not displayed.

A plurality of sub-pixels can be arranged in the display area DA, and various signal lines for driving the plurality of sub-pixels can be arranged.

The non-display area NDA can be an outer area of the display area DA. Various signal lines can be arranged in the non-display area NDA, and various driving circuits can be connected thereto. The non-display area NDA can be bent so as not to be visible from the front or can be covered by a case. The non-display area NDA is also referred to as a bezel or a bezel area.

Referring to FIG. 1A to FIG. 1D, the at least one optoelectronic device 11 and/or 12 in the display device 100 according to embodiments of the present disclosure can be an electronic component positioned on the lower part of the display panel 110 (i.e., on the opposite side of the viewing surface).

External light can enter through the front surface (viewing surface) of the display panel 110, pass through the display panel 110, and be transmitted to the at least one optoelectronic device 11 and/or 12 positioned below the display panel 110.

The at least one optoelectronic device 11 and/or 12 can receive external light transmitted through the display panel 110 and perform a predetermined function according to the received external light. For example, the at least one optoelectronic device 11 and/or 12 can include at least one of an imaging device such as a camera (image sensor), a proximity sensor, and an ambient light sensor.

Referring to FIG. 1A to FIG. 1E, in the display panel 110 according to embodiments of the present disclosure, the display area DA can include a general area NA and at least one optical area OA1 and/or OA2, wherein the general area NA is disposed outside the at least one optical area OA1 and/or OA2.

The at least one optical area OA1 and/or OA2 can be an area that overlaps with the at least one optoelectronic device 11 and/or 12, respectively.

According to the example of FIG. 1A, the display area DA can include a general area NA and a first optical area OA1. Here, at least a portion of the first optical area OA1 can overlap with the first optoelectronic device 11.

In FIG. 1A, the first optical area OA1 is illustrated as having a circular shape; however, the shape of the first optical area OA1 according to the embodiments of the present disclosure is not limited thereto.

For example, as shown in FIG. 1B, the first optical area OA1 can have an octagonal shape, and in addition, it can have various polygonal shapes.

According to the example of FIG. 1C, the display area DA can include a general area NA, a first optical area OA1, and a second optical area OA2. In the example of FIG. 1C, a general area NA can be disposed between the first optical area OA1 and the second optical area OA2. Here, at least a portion of the first optical area OA1 can overlap with the first optoelectronic device 11, and at least a portion of the second optical area OA2 can overlap with the second optoelectronic device 12.

According to the example of FIG. 1D, the display area DA can include a general area NA, a first optical area OA1, and a second optical area OA2. In the example of FIG. 1D, no general area NA can be disposed between the first optical area OA1 and the second optical area OA2. For example, the first optical area OA1 and the second optical area OA2 can be in contact with each other. Here, at least a portion of the first optical area OA1 can overlap with the first optoelectronic device 11, and at least a portion of the second optical area OA2 can overlap with the second optoelectronic device 12.

According to the example of FIG. 1E, the display panel 110 further includes a hole area H, in which the second optoelectronic device 12 is disposed and which is surrounded by the general area NA. In the hole area H, the second optoelectronic device 12 can be positioned above the display panel 110. However, the embodiments of the present disclosure are not limited thereto, and the hole area H can be a second optical area OA2 in which the second optoelectronic device 12 is positioned below the display panel 110 within the display area DA.

The display area DA on the display panel 110 can include the first optical area OA1 and the general area NA.

According to the example of FIG. 1E, a general area NA is disposed between the first optical area OA1 and the hole area H, and the hole area H is disposed on an imaginary centerline that vertically divides the display panel 110. The first optical area OA1 can be spaced apart from the hole area H to the left or right with respect to the imaginary centerline.

In FIG. 1E, the first optical area OA1 and the hole area H are illustrated as having the same size; however, the present disclosure is not limited thereto. For example, the sizes of the first optical area OA1 and the hole area H can be different. For instance, the size of the first optical area OA1 can be smaller than the size of the hole area H.

The at least one optical area OA1 and/or OA2 can include both an image display structure and a light-transmitting structure. For example, since the at least one optical area OA1 and/or OA2 is a part of the display area DA, sub-pixels for image display must be arranged in the at least one optical area OA1 and/or OA2. In addition, the at least one optical area OA1 and/or OA2 must include a light-transmitting structure for allowing light to pass through to the at least one optoelectronic device 11 and/or 12.

Hereinafter, the image display structure can be referred to as an emission area, and the light-transmitting structure can be referred to as a transmissive area.

The at least one optoelectronic device 11 and/or 12 is a device that requires light reception; however, it is positioned on the lower part of the display panel 110 (on the opposite side of the viewing surface) and receives light transmitted through the display panel 110.

The least one optoelectronic device 11 and/or 12 is not exposed on the front surface (viewing surface) of the display panel 110. Accordingly, when a user looks at the front of the display device 100, the optoelectronic device 11 and/or 12 may not be visible to the user.

For example, the first optoelectronic device 11 can be a sensing sensor such as a proximity sensor or an ambient light sensor, and the second optoelectronic device 12 can be a camera. For example, the sensing sensor can be an infrared sensor that detects infrared rays.

Conversely, the first optoelectronic device 11 can be a camera, and the second optoelectronic device 12 can be a sensing sensor.

Hereinafter, for convenience of explanation, an example will be described in which the first optoelectronic device 11 is a sensing sensor, and the second optoelectronic device 12 is a camera. Here, the camera can refer to a camera lens or an image sensor.

When the second optoelectronic device 12 is a camera, the camera is positioned below the display panel 110 but can be a front camera that captures images in the front direction of the display panel 110. Accordingly, a user can take pictures using the camera, which is not visible on the viewing surface while looking at the viewing surface of the display panel 110.

The general area NA and the at least one optical area OA1 and/or OA2 are display areas DA capable of displaying images. However, the general area NA is an area where a light-transmitting structure does not need to be formed, whereas the at least one optical area OA1 and/or OA2 is an area where a light-transmitting structure must be formed.

Accordingly, the at least one optical area OA1 and/or OA2 is required to have a transmittance above a certain level, whereas the general area NA can have no light transmittance or can have a low transmittance below a certain level.

For example, the at least one optical area OA1 and/or OA2 and the general area NA can differ in resolution, sub-pixel arrangement structure, the number of sub-pixels per unit area, electrode structure, wiring structure, electrode arrangement structure, or wiring arrangement structure.

For example, the number of sub-pixels per unit area in the at least one optical area OA1 and/or OA2 can be smaller than that in the general area NA. For example, the resolution of the at least one optical area OA1 and/or OA2 can be lower than that of the general area NA. Here, the number of sub-pixels per unit area is a unit for measuring resolution and can also be referred to as PPI (Pixels Per Inch), which indicates the number of pixels per inch.

For example, the number of sub-pixels per unit area in the first optical area OA1 can be smaller than that in the general area NA. The number of sub-pixels per unit area in the second optical area OA2 can be equal to or greater than that in the first optical area OA1.

Each of the first optical area OA1 and the second optical area OA2 can have various shapes such as a circle, an ellipse, a rectangle, a hexagon, or an octagon. The first optical area OA1 and the second optical area OA2 can have the same shape or different shapes.

Referring to FIG. 1C, when the first optical area OA1 and the second optical area OA2 are in contact with each other, the entire optical area, including the first optical area OA1 and the second optical area OA2, can also have various shapes such as a circle, an ellipse, a rectangle, a hexagon, or an octagon.

Hereinafter, for convenience of explanation, an example will be described in which each of the first optical area OA1 and the second optical area OA2 is circular.

Since the display device 100 according to embodiments of the present disclosure does not require a notch or hole in the display panel 110 for exposing a camera or a sensing sensor, the area of the display area DA may not be reduced.

Accordingly, since the display panel 110 does not require a notch or camera hole for exposing a camera or a sensing sensor, the size of the bezel area can be reduced, and design constraints can be eliminated, thereby increasing the degree of freedom in design.

Even though the at least one optoelectronic device 11 and/or 12 in the display device 100 according to embodiments of the present disclosure is hidden behind the display panel 110, the at least one optoelectronic device 11 and/or 12 must be able to properly receive light and perform its designated function normally.

Additionally, even though the at least one optoelectronic device 11 and/or 12 is hidden behind the display panel 110 and overlaps the display area DA in the display device 100 according to embodiments of the present disclosure, normal image display must be possible in the at least one optical area OA1 and/or OA2, which overlaps the at least one optoelectronic device 11 and/or 12 within the display area DA.

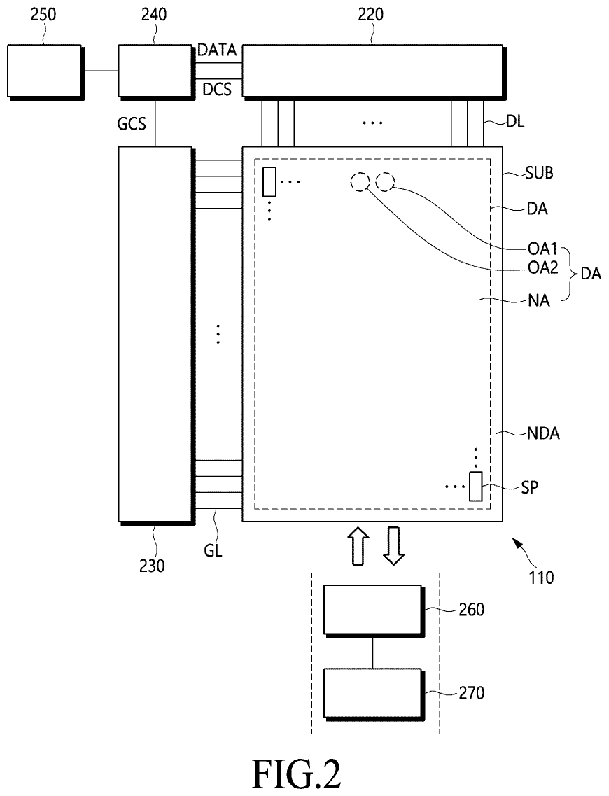

FIG. 2 is a diagram for illustrating the system configuration of a display device 100 according to embodiments of the present disclosure.

Referring to FIG. 2, the display device 100 can include a display panel 110 and a display driving circuit as components for image display.

The display driving circuit is a circuit for driving the display panel 110 and can include a data driving circuit 220, a gate driving circuit 230, and a controller 240.

The display panel 110 can include a display area DA, where an image is displayed, and a non-display area NDA, where an image is not displayed. The non-display area NDA can be an outer area of the display area DA and can also be referred to as a bezel area. The whole or part of the non-display area NDA can be an area visible from the front of the display device 100 or can be bent so as not to be visible from the front of the display device 100.

The display panel 110 can include a substrate SUB and a plurality of sub-pixels SP arranged on the substrate SUB. Additionally, the display panel 110 can further include various types of signal lines for driving the plurality of sub-pixels SP.

The display device 100 according to embodiments of the present disclosure can be a liquid crystal display (LCD) or a self-emissive display in which the display panel 110 emits light by itself. When the display device 100 is a self-emissive display, each of the plurality of sub-pixels SP can include a light-emitting device.

For example, the display device 100 according to embodiments of the present disclosure can be an organic light-emitting display in which the light-emitting device is implemented as an organic light-emitting diode (OLED). In another example, the display device 100 can be an inorganic light-emitting display in which the light-emitting device is implemented as an inorganic light-emitting diode. In yet another example, the display device 100 can be a quantum dot display in which the light-emitting device is implemented as a quantum dot, which is a semiconductor crystal that emits light by itself.

The structure of each of the plurality of sub-pixels SP can vary depending on the type of the display device 100. For example, when the display device 100 is a self-emissive display in which each sub-pixel SP emits light by itself, each sub-pixel SP can include a self-light-emitting device, at least one transistor, and at least one capacitor.

For example, various types of signal lines can include a plurality of data lines DL for transmitting data signals (also referred to as data voltages or image signals) and a plurality of gate lines GL for transmitting gate signals (also referred to as scan signals SCAN).

The plurality of data lines DL and the plurality of gate lines GL can intersect with each other. Each of the plurality of data lines DL can extend in a first direction, and each of the plurality of gate lines GL can extend in a second direction.

Here, the first direction can be a column direction, and the second direction can be a row direction. Alternatively, the first direction can be a row direction, and the second direction can be a column direction.

Hereinafter, for convenience of explanation, an example will be described in which the first direction is the column direction and the second direction is the row direction.

At least one of the plurality of data lines DL that overlaps the at least one optical area OA1 and/or OA2 can include at least one of a data connection line (a first connection line DCL1 or a second connection line DCL2) and a data sub-line.

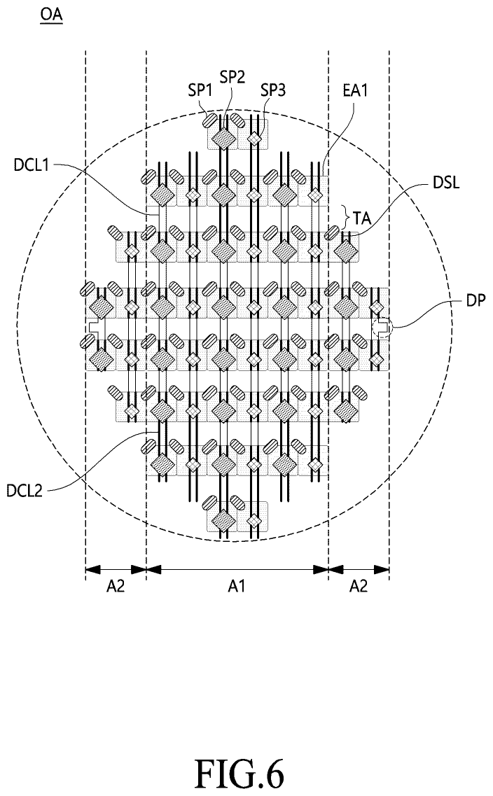

The data connection lines (the first connection line DCL1 and the second connection line DCL2) and data sub-lines will be described in more detail with reference to the embodiments shown in FIG. 6 to FIG. 18.

The data driving circuit 220 is a circuit for driving the plurality of data lines DL and can output data signals to the plurality of data lines DL. The gate driving circuit 230 is a circuit for driving the plurality of gate lines GL and can output gate signals (i.e., scan signals SCAN) to the plurality of gate lines GL.

The controller 240 is a device for controlling the data driving circuit 220 and the gate driving circuit 230 and can control the driving timing of the plurality of data lines DL and the plurality of gate lines GL.

The controller 240 can supply a data driving control signal DCS to the data driving circuit 220 to control it and can supply a gate driving control signal GCS to the gate driving circuit 230 to control it.

The controller 240 can receive input image data from a host system 250 and supply digital image data DATA to the data driving circuit 220 based on the input image data.

The data driving circuit 220 can supply data signals to the plurality of data lines DL according to the driving timing control of the controller 240.

The data driving circuit 220 can receive digital image data DATA from the controller 240, convert the received digital image data DATA into analog data signals, and output the analog data signals to the plurality of data lines DL.

The gate driving circuit 230 can supply gate signals (i.e., scan signals SCAN) to the plurality of gate lines GL according to the timing control of the controller 240. The gate driving circuit 230 can receive, together with various gate driving control signals GCS, a first gate voltage corresponding to a turn-on level voltage, and a second gate voltage corresponding to a turn-off level voltage, generate gate signals, and supply the generated gate signals to the plurality of gate lines GL.

For example, the data driving circuit 220 can be connected to the display panel 110 using a Tape Automated Bonding (TAB) method, can be connected to a bonding pad of the display panel 110 using a Chip On Glass (COG) or Chip On Panel (COP) method, or can be implemented using a Chip On Film (COF) method and connected to the display panel 110.

The gate driving circuit 230 can be connected to the display panel 110 using a Tape Automated Bonding (TAB) method, can be connected to a bonding pad of the display panel 110 using a Chip On Glass (COG) or Chip On Panel (COP) method, or can be connected to the display panel 110 using a Chip On Film (COF) method. Alternatively, the gate driving circuit 230 can be formed in the non-display area NDA of the display panel 110 as a Gate In Panel (GIP) type. The gate driving circuit 230 can be arranged on a substrate SUB or connected to a substrate SUB. For example, when the gate driving circuit 230 is a GIP type, it can be arranged in the non-display area NDA of the substrate SUB. When the gate driving circuit 230 is a COG type or COF type, it can be connected to the substrate SUB.

Meanwhile, at least one of the data driving circuit 220 and the gate driving circuit 230 can be arranged in the display area DA of the display panel 110. For example, at least one of the data driving circuit 220 and the gate driving circuit 230 can be arranged so as not to overlap with the sub-pixels SP, or it can be arranged so that some or all of it overlaps with the sub-pixels SP.

The data driving circuit 220 can be connected to one side of the display panel 110 (e.g., an upper side or a lower side). Depending on the driving method or panel design etc., the data driving circuit 220 can be connected to both sides of the display panel 110 (e.g., both the upper and lower sides) or can be connected to two or more sides among the four sides of the display panel 110.

The gate driving circuit 230 can be connected to one side of the display panel 110 (e.g., a left side or a right side). Depending on the driving method or panel design etc., the gate driving circuit 230 can be connected to both sides of the display panel 110 (e.g., both the left and right sides) or can be connected to two or more sides among the four sides of the display panel 110.

The controller 240 can be implemented as a separate component from the data driving circuit 220 or can be integrated with the data driving circuit 220 as an integrated circuit.

The controller 240 can be a Timing Controller used in conventional display technology, a control device that includes a timing controller and performs additional control functions, a control device different from a timing controller, or a circuit within a control device. The controller 240 can be implemented as various circuits or electronic components such as an Integrated Circuit (IC), a Field Programmable Gate Array (FPGA), an Application Specific Integrated Circuit (ASIC), or a processor.

The controller 240 can be mounted on a Printed Circuit Board (PCB) or a Flexible Printed Circuit (FPC) and can be electrically connected to the data driving circuit 220 and the gate driving circuit 230 through the Printed Circuit Board (PCB) or the Flexible Printed Circuit (FPC).

The controller 240 can transmit and receive signals with the data driving circuit 220 according to at least one predetermined interface. For example, the interface can include LVDS (Low Voltage Differential Signaling), EPI (Embedded Clock Point-to-Point Interface), and SPI (Serial Peripheral Interface).

The display device 100 according to embodiments of the present disclosure can include a touch sensor TS and a touch sensing circuit for providing a touch sensing function in addition to an image display function. The touch sensing circuit can sense the touch sensor TS to detect whether a touch has occurred by a touch object such as a finger or a pen, or to detect the touch position.

The touch sensing circuit can include a touch driving circuit 260 for driving and sensing the touch sensor TS to generate and output touch sensing data and a touch controller 270 for detecting a touch event or detecting a touch position using the touch sensing data.

The touch sensor TS can include a plurality of touch electrodes. The touch sensor TS can further include a plurality of touch lines for electrically connecting the plurality of touch electrodes with the touch driving circuit 260.

The touch sensor TS can exist externally as a touch panel on the display panel 110 or can be integrated inside the display panel 110. When the touch sensor TS exists externally as a touch panel on the display panel 110, it is called an external touch sensor TS. When the touch sensor TS is external, the touch panel and the display panel 110 are separately manufactured and can be combined during the assembly process. An external touch panel can include a substrate SUB for a touch panel and a plurality of touch electrodes on the substrate SUB for a touch panel.

When the touch sensor TS is integrated inside the display panel 110, it can be formed on the substrate SUB during the manufacturing process of the display panel 110, along with the signal lines and electrodes related to display driving.

The touch driving circuit 260 can supply a touch driving signal to at least one of the plurality of touch electrodes and can sense at least one of the plurality of touch electrodes to generate touch sensing data.

The touch sensing circuit can perform touch sensing using either a self-capacitance sensing method or a mutual-capacitance sensing method.

When the touch sensing circuit performs touch sensing using the self-capacitance sensing method, it can perform touch sensing based on the capacitance between each touch electrode and a touch object (e.g., a finger or a pen).

According to the self-capacitance sensing method, each of the plurality of touch electrodes can function as both a driving touch electrode and a sensing touch electrode. The touch driving circuit 260 can drive all or some of the plurality of touch electrodes and can sense all or some of the plurality of touch electrodes.

When the touch sensing circuit performs touch sensing using the mutual-capacitance sensing method, it can perform touch sensing based on the capacitance between touch electrodes.

According to the mutual-capacitance sensing method, the plurality of touch electrodes are divided into driving touch electrodes and sensing touch electrodes. The touch driving circuit 260 can drive the driving touch electrodes and sense the sensing touch electrodes.

The touch driving circuit 260 and the touch controller 270 included in the touch sensing circuit can be implemented as separate devices or as a single device. Additionally, the touch driving circuit 260 and the data driving circuit 220 can be implemented as separate devices or as a single device.

The display device 100 can further include a power supply circuit for supplying various power sources to the display driving circuit and/or the touch sensing circuit.

The display device 100 according to embodiments of the present disclosure can be a mobile terminal such as a smartphone or tablet, or it can be a monitor or television (TV) of various sizes. However, the present disclosure is not limited thereto and can be a display of various types and sizes capable of outputting information or images.

As described above, the display area DA of the display panel 110 can include a general area NA and the at least one optical area OA1 and/or OA2.

The general area NA and the at least one optical area OA1 and/or OA2 are areas capable of image display. However, the general area NA is an area where a light-transmitting structure does not need to be formed, whereas the at least one optical area OA1 and/or OA2 is an area where a light-transmitting structure must be formed.

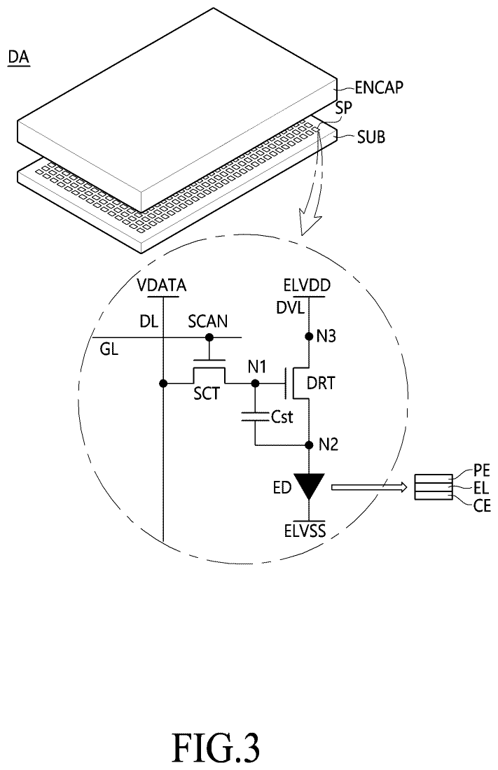

FIG. 3 is a diagram for illustrating an example of a sub-pixel SP according to embodiments of the present disclosure.

Referring to FIG. 3, each of the sub-pixels SP arranged in the general area NA, the first optical area OA1, and the second optical area OA2 included in the display area DA of the display panel 110 can include a light-emitting device ED arranged on the substrate SUB and in the emission area, a driving transistor DRT for driving the light-emitting device ED, a scan transistor SCT for delivering a data voltage VDATA to a first node N1 of the driving transistor DRT, and a storage capacitor Cst for maintaining a constant voltage during one frame.

The driving transistor DRT can include a first node N1 where the data voltage is applied, a second node N2 electrically connected to the light-emitting device ED, and a third node N3 where a driving voltage ELVDD is applied from a driving voltage line DVL.

The first node N1 of the driving transistor DRT can be a gate node of the driving transistor DRT and can be electrically connected to a source node or drain node of the scan transistor SCT.

The second node N2 of the driving transistor DRT can be a source node or drain node of the driving transistor DRT and can be electrically connected to a pixel electrode PE of the light-emitting device ED.

The third node N3 of the driving transistor DRT can be a drain node or source node of the driving transistor DRT.

The storage capacitor Cst can be connected between the first node N1 and the second node N2 of the driving transistor DRT. The storage capacitor Cst charges an amount of charge corresponding to the voltage difference between its two terminals and serves to maintain the voltage difference for a predetermined frame time. Accordingly, the corresponding sub-pixel SP can emit light during the predetermined frame time.

The scan transistor SCT can be controlled by a gate signal (i.e., a scan signal SCAN) and can be connected between the first node N1 of the driving transistor DRT and the data line DL.

The scan transistor SCT can be turned on by a gate signal of a turn-on level voltage supplied from the gate line GL and can deliver the data voltage VDATA supplied from the data line DL to the first node N1 of the driving transistor DRT.

The scan transistor SCT and the driving transistor DRT can be n-type transistors or p-type transistors.

Here, when the scan transistor SCT is an n-type transistor, the turn-on level voltage of the gate signal can be a high-level voltage. When the scan transistor SCT is a p-type transistor, the turn-on level voltage of the gate signal can be a low-level voltage.

The light-emitting device ED can include a pixel electrode PE, an emission layer EL, and a common electrode CE. A base voltage ELVSS can be applied to the common electrode CE.

For example, the pixel electrode PE can be an anode electrode, and the common electrode CE can be a cathode electrode. Conversely, the pixel electrode PE can be a cathode electrode, and the common electrode CE can be an anode electrode. Hereinafter, for convenience of explanation, it is assumed that the pixel electrode PE is an anode electrode and the common electrode CE is a cathode electrode.

For example, the light-emitting device ED can be an organic light-emitting diode (OLED), an inorganic light-emitting diode, or a quantum dot light-emitting device. In this case, when the light-emitting device ED is an organic light-emitting diode, the emission layer EL of the light-emitting device ED can include an organic emission layer containing organic materials.

The storage capacitor Cst can be an external capacitor, which is intentionally designed outside the driving transistor DRT, rather than a parasitic capacitor (e.g., Cgs, Cgd), which is an internal capacitor that exists between the gate node and the source node (or drain node) of the driving transistor DRT.

Since the circuit elements within each sub-pixel SP, particularly the light-emitting device ED, are vulnerable to external moisture and oxygen, an encapsulation layer ENCAP can be arranged in the display panel 110 to prevent moisture or oxygen from penetrating into the circuit elements, particularly the light-emitting device ED. The encapsulation layer ENCAP can be arranged to cover the light-emitting devices ED.

The structure of the sub-pixel SP shown in FIG. 3 is merely an example and can be variously modified to include one or more additional transistors or one or more additional capacitors.

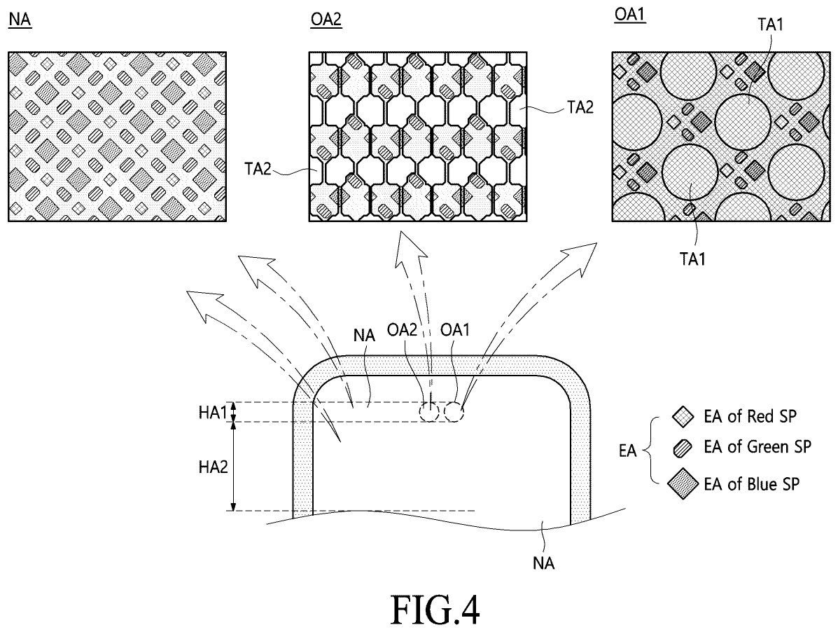

FIG. 4 is a diagram for illustrating the arrangement of sub-pixels SP in the general area NA and the optical areas OA1 and OA2 according to embodiments of the present disclosure.

Referring to FIG. 4, a plurality of sub-pixels SP can be arranged in each of the general area NA, the first optical area OA1, and the second optical area OA2 included in the display area DA.

For example, the plurality of sub-pixels SP can include red sub-pixels (Red SP) that emit red light, green sub-pixels (Green SP) that emit green light, and blue sub-pixels (Blue SP) that emit blue light.

Accordingly, each of the general area NA, the first optical area OA1, and the second optical area OA2 can include a plurality of emission areas EA of red sub-pixels Red SP, a plurality of emission areas EA of green sub-pixels Green SP, and a plurality of emission areas EA of blue sub-pixels Blue SP.

Hereinafter, for convenience of explanation, the emission areas EA included in the first optical area OA1 and the second optical area OA2 can be referred to as first emission areas EA1, and the emission areas EA included in the general area NA can be referred to as second emission areas EA2.

Referring to FIG. 4, the general area NA can include a plurality of emission areas EA but may not include a transmissive area TA (i.e., a light-transmitting structure).

However, the first optical area OA1 and the second optical area OA2 can include not only a plurality of emission areas EA but also a plurality of transmissive areas TA.

In other words, the first optical area OA1 can include a plurality of emission areas EA and a plurality of the first transmissive areas TA1, and the second optical area OA2 can include a plurality of emission areas EA and a plurality of the second transmissive areas TA2.

The plurality of emission areas EA and the plurality of transmissive areas TA1 and TA2 can be distinguished based on whether they allow light transmission. For example, the plurality of emission areas EA can be areas where light transmission is not possible, whereas the plurality of transmissive areas TA1 and TA2 can be areas where light transmission is possible.

Additionally, the plurality of emission areas EA and the plurality of transmissive areas TA1 and TA2 can be distinguished based on the presence or absence of a specific metal layer. For example, in the plurality of emission areas EA, a cathode electrode CE can be formed, whereas in the plurality of transmissive areas TA1 and TA2, a cathode electrode CE may not be formed. Similarly, a light shield layer can be formed in the plurality of emission areas EA, whereas a light shield layer may not be formed in the plurality of transmissive areas TA1 and TA2. The cathode electrode CE can be a common electrode.

Since the first optical area OA1 includes a plurality of the first transmissive areas TA1, and the second optical area OA2 also includes a plurality of the second transmissive areas TA2, the first optical area OA1 and the second optical area OA2 can be defined as areas where light (e.g., external light) can pass through.

The transmittance (degree of transmission) of the first optical area OA1 and the transmittance of the second optical area OA2 can be the same.

In this case, the first transmissive area TA1 of the first optical area OA1 and the second transmissive area TA2 of the second optical area OA2 can have the same shape or size. Alternatively, even if the first transmissive area TA1 of the first optical area OA1 and the second transmissive area TA2 of the second optical area OA2 have different shapes or sizes, the ratio of the first transmissive area TA1 within the first optical area OA1 and the ratio of the second transmissive area TA2 within the second optical area OA2 can be the same.

On the other hand, the transmittance (degree of transmission) of the first optical area OA1 and the transmittance of the second optical area OA2 can be different.

In this case, the first transmissive area TA1 of the first optical area OA1 and the second transmissive area TA2 of the second optical area OA2 can have different shapes or sizes. Alternatively, even if the first transmissive area TA1 of the first optical area OA1 and the second transmissive area TA2 of the second optical area OA2 have the same shape or size, the ratio of the first transmissive area TA1 within the first optical area OA1 and the ratio of the second transmissive area TA2 within the second optical area OA2 can be different.

For example, if the first optoelectronic device 11, which overlaps the first optical area OA1, is a camera, and the second optoelectronic device 12, which overlaps the second optical area OA2, is a sensing sensor, the camera can require a greater amount of light than the sensing sensor.

Accordingly, the transmittance (degree of transmission) of the first optical area OA1 can be higher than the transmittance of the second optical area OA2.

In this case, the first transmissive area TA1 of the first optical area OA1 can be larger than the second transmissive area TA2 of the second optical area OA2. Alternatively, even if the first transmissive area TA1 of the first optical area OA1 and the second transmissive area TA2 of the second optical area OA2 have the same size, the ratio of the first transmissive area TA1 within the first optical area OA1 can be greater than the ratio of the second transmissive area TA2 within the second optical area OA2.

Referring to FIG. 4, in the embodiments of the present disclosure, the transmissive areas TA1 and TA2 can also be referred to as transparent areas, and transmittance can also be referred to as transparency.

Additionally, in the embodiments of the present disclosure, it is assumed that the first optical area OA1 and the second optical area OA2 are located at an upper portion of the display area DA of the display panel 110 and are arranged side by side.

The horizontal display area in which the first optical area OA1 and the second optical area OA2 are arranged can be defined as the first horizontal display area HA1, and the horizontal display area in which the first optical area OA1 and the second optical area OA2 are not arranged can be defined as the second horizontal display area HA2.

The first horizontal display area HA1 can include the general area NA, the first optical area OA1, and the second optical area OA2. The second horizontal display area HA2 can include only the general area NA.

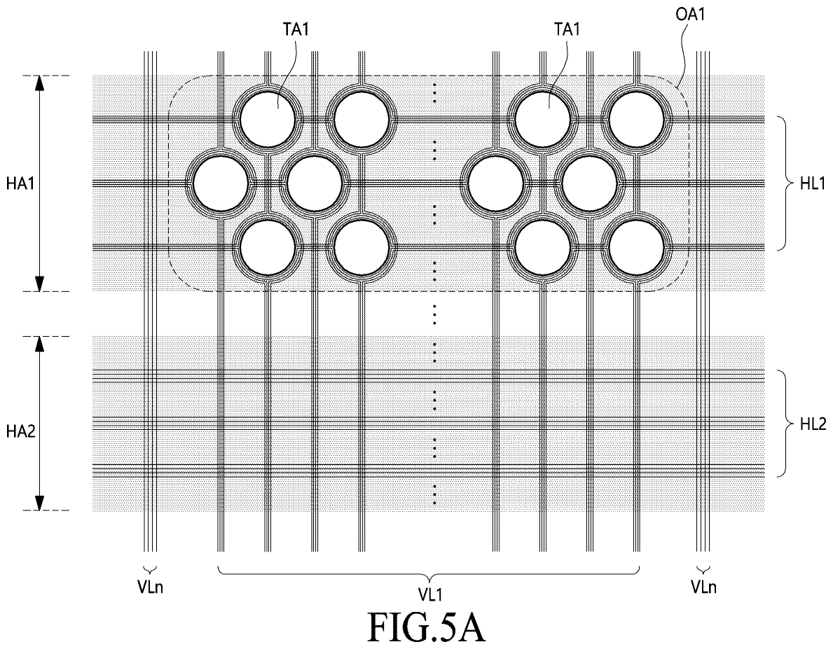

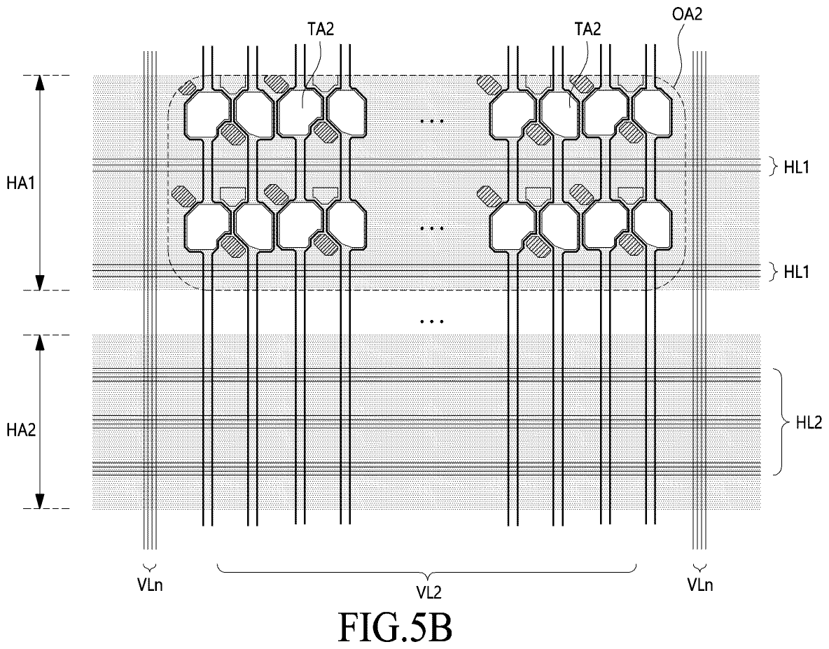

FIG. 5A and FIG. 5B are diagrams for illustrating the arrangement of signal lines in the display panel 110 according to embodiments of the present disclosure.

Specifically, FIG. 5A illustrates a layout diagram of signal lines in each of the first optical area OA1 and the general area NA according to embodiments of the present disclosure, and FIG. 5B illustrates a layout diagram of signal lines in each of the second optical area OA2 and the general area NA according to embodiments of the present disclosure.

The first horizontal display area HA1 shown in FIG. 5A and FIG. 5B is a part of the first horizontal display area HA1 in the display panel 110, and the second horizontal display area HA2 is a part of the second horizontal display area HA2 in the display panel 110.

The first optical area OA1 shown in FIG. 5A is a part of the first optical area OA1 in the display panel 110, and the second optical area OA2 shown in FIG. 5B is a part of the second optical area OA2 in the display panel 110.

Referring to FIG. 5A and FIG. 5B, the first horizontal display area HA1 can include the general area NA, the first optical area OA1, and the second optical area OA2. The second horizontal display area HA2 can include the general area NA.

Various types of horizontal lines HL1 and HL2 and various types of vertical lines VLn, VL1, and VL2 can be arranged in the display panel 110.

In the embodiments of the present disclosure, the horizontal direction and the vertical direction refer to two intersecting directions, and they can vary depending on the viewing orientation. For example, in the embodiments of the present disclosure, the horizontal direction can refer to the direction in which a gate line GL extends and is arranged, and the vertical direction can refer to the direction in which a data line DL extends and is arranged. Thus, the terms horizontal and vertical are used as examples.

The horizontal lines arranged in the display panel 110 can include the first horizontal lines HL1, which are arranged in the first horizontal display area HA1, and the second horizontal lines HL2, which are arranged in the second horizontal display area HA2.

The horizontal lines arranged in the display panel 110 can be gate lines GL. For example, the first horizontal lines HL1 and the second horizontal lines HL2 can be gate lines GL. The gate lines GL can include various types of gate lines depending on the structure of the sub-pixel SP.

The vertical lines arranged in the display panel 110 can include general vertical lines VLn, which are arranged only in the general area NA, first vertical lines VL1, which pass through both the first optical area OA1 and the general area NA, and second vertical lines VL2, which pass through both the second optical area OA2 and the general area NA.

The vertical lines arranged in the display panel 110 can include data lines DL and driving voltage lines DVL. Additionally, they can further include reference voltage lines, initialization voltage lines, and others. For example, the general vertical lines VLn, the first vertical lines VL1, and the second vertical lines VL2 can include data lines DL and driving voltage lines DVL, and can further include reference voltage lines and initialization voltage lines.

In the embodiments of the present disclosure, the term “horizontal” in second horizontal lines HL2 only means that the signal is transmitted from the left (or right) to the right (or left); it does not necessarily mean that the second horizontal lines HL2 extend strictly in a straight horizontal direction. For example, although the second horizontal lines HL2 are depicted as straight lines in FIG. 5A and FIG. 5B, they can instead include bent or curved sections. Similarly, the first horizontal lines HL1 can also include bent or curved sections.

In the embodiments of the present disclosure, the term “vertical” in general vertical lines VLn only means that the signal is transmitted from the top (or bottom) to the bottom (or top); it does not necessarily mean that the general vertical lines VLn extend strictly in a straight vertical direction. For example, although the general vertical lines VLn are depicted as straight lines in FIG. 5A and FIG. 5B, they can instead include bent or curved sections. Similarly, the first vertical lines VL1 and the second vertical lines VL2 can also include bent or curved sections.

Referring to FIG. 5A, the first optical area OA1 included in the first horizontal display area HA1 can include a plurality of emission areas EA and a plurality of the first transmissive areas TA1. The outer area of the plurality of the first transmissive areas TA1 in the first optical area OA1 can include a plurality of emission areas EA.

To improve the transmittance of the first optical area OA1, the first horizontal lines HL1, which pass through the first optical area OA1, can be arranged to avoid the plurality of the first transmissive areas TA1 within the first optical area OA1.

Accordingly, each of the first horizontal lines HL1 passing through the first optical area OA1 can include a curved section or a bending section that bypasses the outer boundary of the plurality of the first transmissive areas TA1 in the first optical area OA1.

As a result, the first horizontal lines HL1 arranged in the first horizontal display area HA1 and the second horizontal lines HL2 arranged in the second horizontal display area HA2 can differ in shape or length. For example, the first horizontal line HL1, which passes through the first optical area OA1, and the second horizontal line HL2, which does not pass through the first optical area OA1, can differ in shape or length.

Additionally, to improve the transmittance of the first optical area OA1, the first vertical lines VL1 passing through the first optical area OA1 can be arranged to avoid the plurality of the first transmissive areas TA1 within the first optical area OA1.

Accordingly, each of the first vertical lines VL1 passing through the first optical area OA1 can include a curved section or a bending section that bypasses the outer boundary of the plurality of first transmissive areas TA1 in the first optical area OA1.

As a result, the first vertical line VL1, which passes through the first optical area OA1, and the general vertical line VLn, which does not pass through the first optical area OA1 and is arranged in the general area NA, can differ in shape or length.

The first transmissive area TA1 included in the first optical area OA1 within the first horizontal display area HA1 can be arranged diagonally.

In in the first optical area OA1 within the first horizontal display area HA1, a plurality of emission areas EA can be arranged between two adjacent transmissive area TA1 in the left-right direction. Similarly, in the first optical area OA1 within the first horizontal display area HA1, a plurality of emission areas EA can be arranged between two adjacent transmissive area TA1 in the top-bottom direction.

Each of the first horizontal lines HL1 arranged in the first horizontal display area HA1, for example, the first horizontal lines HL1 passing through the first optical area OA1, can include at least one curved section or bending section that bypasses the outer boundary of the first transmissive area TA1.

Referring to FIG. 5B, the second optical area OA2 included in the first horizontal display area HA1 can include a plurality of emission areas EA and a plurality of second transmissive areas TA2. In the second optical area OA2, the outer region of the plurality of second transmissive areas TA2 can include a plurality of emission areas EA.

The arrangement and position of the plurality of emission areas EA and the plurality of second transmissive areas TA2 within the second optical area OA2 can be the same as those of the plurality of emission areas EA and the plurality of first transmissive areas TA1 within the first optical area OA1 in FIG. 5A.

Alternatively, as shown in FIG. 5B, the arrangement and position of the plurality of emission areas EA and the plurality of second transmissive areas TA2 within the second optical area OA2 can differ from those of the plurality of emission areas EA and the plurality of first transmissive areas TA1 within the first optical area OA1 in FIG. 5A.

For example, referring to FIG. 5B, in the second optical area OA2, the plurality of second transmissive areas TA2 can be arranged in the horizontal direction (left-right direction). Between two horizontally adjacent transmissive area TA2, emission areas EA may not be arranged. Additionally, the plurality of emission areas EA in the second optical area OA2 can be arranged between the second transmissive area TA2 that are adjacent in the vertical direction (top-bottom direction). For example, a plurality of emission areas EA can be arranged between two rows of transmissive area TA2.

When the first horizontal lines HL1 pass through the second optical area OA2 and its surrounding general area NA in the first horizontal display area HA1, they can pass in the same form as in FIG. 5A.

Alternatively, when the first horizontal lines HL1 pass through the second optical area OA2 and its surrounding general area NA in the first horizontal display area HA1, they can pass in a different form than in FIG. 5A.

This is because the arrangement and position of the plurality of emission areas EA and the plurality of second transmissive areas TA2 in the second optical area OA2 in FIG. 5B differ from those of the plurality of emission areas EA and the plurality of first transmissive areas TA1 in the first optical area OA1 in FIG. 5A.

When the first horizontal lines HL1 pass through the second optical area OA2 and its surrounding general area NA in the first horizontal display area HA1, they can pass in a straight form between the vertically adjacent transmissive areas TA2 without a curved section or bending section.

In other words, a single first horizontal line HL1 can have a curved section or bending section in the first optical area OA1, but it may not have a curved section or bending section in the second optical area OA2.

To improve the transmittance of the second optical area OA2, the second vertical lines VL2 passing through the second optical area OA2 can be arranged to avoid the plurality of second transmissive areas TA2 within the second optical area OA2.

Accordingly, each of the second vertical lines VL2 passing through the second optical area OA2 can include a curved section or a bending section that bypasses the outer boundary of the plurality of second transmissive areas TA2.

As a result, the second vertical line VL2, which passes through the second optical area OA2, and the general vertical line VLn, which does not pass through the second optical area OA2 and is arranged in the general area NA, can differ in shape or length.

As shown in FIG. 5A, the first horizontal line HL1 passing through the first optical area OA1 can have curved sections or bending sections that bypass the outer boundary of the plurality of first transmissive areas TA1 in the first optical area OA1.

Accordingly, the length of the first horizontal line HL1 passing through the first optical area OA1 and the second optical area OA2 can be slightly longer than the length of the second horizontal line HL2, which is arranged only in the general area NA without passing through the first optical area OA1 and the second optical area OA2.

As a result, the resistance of the first horizontal line HL1 (hereinafter also referred to as first resistance) passing through the first optical area OA1 and the second optical area OA2 can be slightly higher than the resistance of the second horizontal line HL2 (hereinafter also referred to as second resistance) arranged only in the general area NA without passing through the first optical area OA1 and the second optical area OA2.

Referring to FIG. 5A and FIG. 5B, due to the light-transmission structure, the first optical area OA1, which at least partially overlaps the first optoelectronic device 11, includes a plurality of first transmissive areas TA1, and the second optical area OA2, which at least partially overlaps the second optoelectronic device 12, includes a plurality of second transmissive areas TA2. Accordingly, the first optical area OA1 and the second optical area OA2 can have fewer sub-pixels per unit area than the general area NA.

The number of sub-pixels SP connected to the first horizontal line HL1, which passes through the first optical area OA1 and the second optical area OA2, can differ from the number of sub-pixels SP connected to the second horizontal line HL2, which is arranged only in the general area NA without passing through the first optical area OA1 and the second optical area OA2.

The number of sub-pixels SP connected to the first horizontal line HL1 (hereinafter referred to as first number) passing through the first optical area OA1 and the second optical area OA2 can be smaller than the number of sub-pixels SP connected to the second horizontal line HL2 (hereinafter referred to as second number) arranged only in the general area NA without passing through the first optical area OA1 and the second optical area OA2.

The difference between the first number and the second number can vary depending on the resolution difference between the first optical area OA1 or the second optical area OA2, and the general area NA. For example, the larger the resolution difference between the first optical area OA1 or the second optical area OA2, and the general area NA, the larger the difference between the first number and the second number can be.

As described above, the number of sub-pixels SP connected to the first horizontal line HL1, which passes through the first optical area OA1 and the second optical area OA2 (hereinafter referred to as the first number), is smaller than the number of sub-pixels SP connected to the second horizontal line HL2, which is arranged only in the general area NA without passing through the first optical area OA1 and the second optical area OA2 (hereinafter referred to as the second number). Accordingly, the overlapping area between the first horizontal line HL1 and surrounding electrodes or lines can be smaller than the overlapping area between the second horizontal line HL2 and surrounding electrodes or lines.

Accordingly, the parasitic capacitance (hereinafter referred to as first capacitance) formed between the first horizontal line HL1 and surrounding electrodes or lines can be significantly smaller than the parasitic capacitance (hereinafter referred to as second capacitance) formed between the second horizontal line HL2 and surrounding electrodes or lines.

Considering the relationship between the first resistance and the second resistance (first resistance≥second resistance) and the relationship between the first capacitance and the second capacitance (first capacitance<<second capacitance), the RC (Resistance-Capacitance) value of the first horizontal line HL1 (hereinafter also referred to as the first RC value), which passes through the first optical area OA1 and the second optical area OA2, can be much smaller than the RC value of the second horizontal line HL2 (hereinafter also referred to as the second RC value), which is arranged only in the general area NA without passing through the first optical area OA1 and the second optical area OA2 (first RC value<<second RC value).

Due to the difference between the first RC value of the first horizontal line HL1 and the second RC value of the second horizontal line HL2 (hereinafter referred to as RC load deviation), the signal transmission characteristics through the first horizontal line HL1 and the second horizontal line HL2 can differ.

Hereinafter, for ease of explanation, at least one of the first optical area OA1 and/or the second optical area OA2 can be referred to as the optical area OA, and at least one of the plurality of first transmissive areas TA1 in the first optical area OA1 and the plurality of second transmissive areas TA2 in the second optical area OA2 can be referred to as the transmissive area TA.

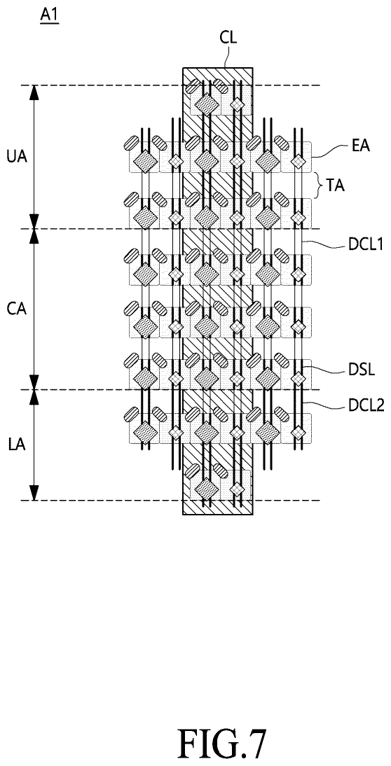

FIG. 6 and FIG. 7 are diagrams illustrating the optical area OA according to embodiments of the present disclosure.

Specifically, FIG. 6 illustrates a plan view of the optical area OA according to embodiments of the present disclosure, and FIG. 7 illustrates a plan view in which only the first area A1 is represented in the plan view of FIG. 6.

Referring to FIG. 6 and FIG. 7, the optical area OA can include a plurality of transmissive areas TA and a plurality of first emission areas EA1.

In FIGS. 6 and 7, for ease of explanation, the optical area OA is illustrated such that the first emission areas EA1 are arranged only in the odd-numbered rows, and the transmissive areas TA are arranged only in the even-numbered rows. However, embodiments of the present disclosure are not limited thereto, and at least one transmissive area TA can be additionally arranged between the first emission areas EA1 in a single row.

In each of the plurality of first emission areas EA1, at least one sub-pixel selected from a first-color sub-pixel SP1 (e.g., green), a second-color sub-pixel SP2 (e.g., blue), and a third-color sub-pixel SP3 (e.g., red) can be arranged.

For example, in the plurality of first emission areas EA1, a second-color sub-pixel SP2 can be arranged in a first-1 emission area, a third-color sub-pixel SP3 can be arranged in a first-2 emission area adjacent to the first-1 emission area, and a first-color sub-pixel SP1 can be arranged at the boundary between the first-1 emission area and the first-2 emission area. However, embodiments of the present disclosure are not limited thereto.

The shape and size of at least two or more sub-pixels among the first-color sub-pixel SP1, the second-color sub-pixel SP2, and the third-color sub-pixel SP3 can be either the same or different.

According to the examples in FIG. 6 and FIG. 7, considering the lifetime and luminous efficiency of the emission material for each color, the second-color sub-pixel SP2 can be formed larger than the first-color sub-pixel SP1 and the third-color sub-pixel SP3. However, embodiments of the present disclosure are not limited thereto.

In order to improve the transmittance in the optical area OA, it is necessary to reduce the use of low-transmittance wiring, such as metal wiring, in the transmissive area TA. In other words, applying high-transmittance wiring to the transmissive area TA needs to be considered.

However, high-transmittance wiring has higher resistance compared to conventional wiring (e.g., low-transmittance wiring or metal wiring). Due to the structural characteristics of the optical area OA, which is implemented in a circular shape, applying high-transmittance wiring to all transmissive areas TA can cause a significant resistance difference between the center region (with longer wiring) and the edge region (with shorter wiring), leading to luminance variation issues.

Accordingly, the display device 100 according to embodiments of the present disclosure applies high-transmittance wiring to a plurality of transmissive areas TA. However, by differentially applying high-transmittance wiring while considering the resistance difference between the center region and the edge region, the display device 100 can minimize luminance variation caused by wiring resistance differences while improving transmittance in the plurality of transmissive areas TA.

Hereinafter, examples of differentially applying high-transmittance wiring according to aspects of the present disclosure will be described in detail.

For example, in the emission areas EA, since there is no requirement in terms of transmittance, the data lines DL (e.g., the data sub-lines DSL and the second connection line DCL2) can be made of metals such as Ti, Al, or Cu.

However, in the transmissive areas TA, due to the transmittance requirement, the data connection lines DCL (e.g., the first connection line DCL 1) are made of Transparent Conductive Oxide (TCO) materials.

Specifically, in an area where a plurality of data lines DL overlap the optical area OA, the plurality of data lines DL can include a plurality of data connection lines, which are disposed in a first direction in at least one of the plurality of transmissive areas TA, and a plurality of data sub-lines DSL, which are disposed in a first direction in the plurality of first emission areas EA1 and electrically connected to at least one of the corresponding data connection lines, for example, at least one of at least one first connection line DCL1 and at least one second connection line DCL2.

The plurality of data connection lines can include at least one first connection line DCL1, which is disposed in the first area A1 and the second area A2 of the optical area OA, and at least one second connection line DCL2, which is disposed in the first area A1 and has a lower resistance than the first connection line DCL1.

For example, the first connection line DCL1 can be high-transmittance wiring with a transmittance of 80% to 99%. As an example, the first connection line DCL1 can include at least one material selected from ITO (Indium Tin Oxide), IGZO (Indium Gallium Zinc Oxide), and IZO (Indium Zinc Oxide), which are TCO materials. Therefore, the first connection line DCL1 can have a higher transmittance than any one of the the second connection line DCL2 and the data sub-lines DSL.

The second connection line DCL2 and the data sub-lines DSL can be wiring with a sheet resistance of 0.01 to 0.05. As an example, the second connection line DCL2 and the data sub-lines DSL can include aluminum (Al). In other words, the second connection line DCL2 and the data sub-lines DSL can be wiring made of the same material. For example, like the second connection line DCL2, the data sub-lines DSL can have a lower resistance than the first connection line DCL1.

However, embodiments of the present disclosure are not limited thereto, and at least one of the plurality of data sub-lines DSL can include the same material as the first connection line DCL1.

For example, the first connection line DCL1 can be formed in a different layer from the second connection line DCL2 and the data sub-lines DSL. The second connection line DCL2 and the data sub-lines DSL can be formed of the same material in the same layer.

According to the examples in FIG. 6 and FIG. 7, the first area A1 is a region located at the center of the optical area OA, and the second area A2 is a region located on each of the first side (e.g., left side) and the second side (e.g., right side) of the first area A1.

For example, in the display device 100 according to embodiments of the present disclosure, the first connection line DCL1, which is high-transmittance/high-resistance wiring, and the second connection line DCL2, which is low-resistance wiring, are differentially arranged in the first area A1, which corresponds to the center of the optical area OA. Meanwhile, in the second area A2, which corresponds to the edge of the optical area OA, only the first connection line DCL1 (high-transmittance/high-resistance wiring) is arranged. Accordingly, the resistance difference between the long wiring at the center and the short wiring at the edges can be minimized.

According to embodiments of the present disclosure, the display device 100 can be designed to minimize the difference in wiring resistance between the center and edge regions by varying the wiring widths of at least one of the plurality of data connection lines disposed in the first area A1 and at least one of the plurality of data connection lines disposed in the second area A2 among the plurality of data connection lines.

For example, at least one data connection line disposed in the first area A1 among the plurality of data connection lines can be designed with a greater wiring width than at least one data connection line disposed in the second area A2 among the plurality of data connection lines, thus differentially designing the wiring width.

More specifically, in the display device 100, the first connection line DCL1 disposed in the center line region CL, where the wiring length is the longest, can be designed with the largest wiring width, and the wiring width of the first connection line DCL1 can gradually decrease as it moves away from the center line region CL.

According to embodiments of the present disclosure, in order to minimize the difference in wiring resistance between the center region and the edge region, the display device 100 can be designed such that at least one of the plurality of data connection lines disposed in the first area A1 and at least one of the plurality of data connection lines disposed in the second area A2 among the plurality of data connection lines have different wiring lengths.

In the display device 100 according to embodiments of the present disclosure, any of wirings disposed in the second area A2 can be lines with curves or angular turns, wherein the lines with curves or angular turns can include a zigzag pattern (i.e., DP shown in FIG. 6).

Specifically, the wirings disposed in the second area A2, which are lines with curves or angular turns, can include any one of a power line, a power connection line, a low potential line, the data connection line DCL, and the data sub-line DSL.

For example, at least one data connection line disposed in the second area A2 among the plurality of data connection lines DCL can be lines with curves or angular turns to differentially design the wiring length of the data connection lines. Further, the at least one data connection lines DCL disposed in the second area A2 can be lines with a zigzag pattern DP.

In another example, in order to minimize the resistance difference between the center and edge regions of the optical area OA, at least one of the plurality of data sub-lines DSL disposed in the second area A2 can be lines with curves or angular turns. Further, at least one data sub-lines DSL disposed in the second area A2 can be lines with a zigzag pattern.

Referring to FIG. 7, the first area A1 can be divided into an upper area UA, an intermediate area CA, and a lower area LA. In the first area A1, the first connection line DCL1 can be disposed in the intermediate area CA, and the second connection line DCL2 can be disposed in at least one of the upper area UA and the lower area LA.

In the first area A1, the first connection line DCL1 can be disposed in at least one of the upper area UA and the lower area LA. As a result, at least one of the upper area UA and the lower area LA can include both the first connection line DCL1 and the second connection line DCL2 arranged together.

In other words, in order to minimize the resistance difference between the center and edge regions of the optical area OA, the display device 100 according to embodiments of the present disclosure can differentially arrange the first connection line DCL1 and the second connection line DCL2. However, to minimize the decrease in transmittance in the transmissive area TA, the second connection line DCL2 can be disposed only in the upper area UA and/or the lower area LA of the first area A1.

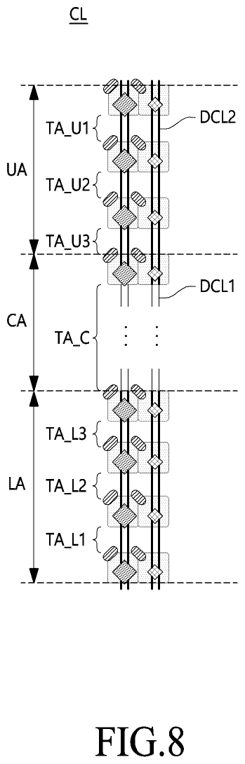

FIG. 8 to FIG. 13 are diagrams for illustrating embodiments according to various combinations of the first connection line DCL1 and the second connection line DCL2 in the display device 100 according to embodiments of the present disclosure.

Specifically, FIG. 8 to FIG. 13 illustrate embodiments according to various combinations of the first connection line DCL1 and the second connection line DCL2 in the center line region CL shown in FIG. 7.

Referring to FIG. 8 to FIG. 13, in the first area A1, the first connection line DCL1 can be disposed in at least one of the transmissive areas TA located in at least one of the upper area UA, the intermediate area CA, and the lower area LA. The second connection line DCL2 can be disposed in at least one of the transmissive areas TA located in at least one of the upper area UA and the lower area LA.

According to the examples of FIG. 8 to FIG. 13, in each of the plurality of intermediate transmissive areas TA_C located in the intermediate area CA, the first connection line DCL1 can be arranged.

According to the example of FIG. 8, in each of the first to third upper transmissive areas TA_U1, TA_U2 and TA_U3 located in the upper area UA and in each of the first to third lower transmissive areas TA_L1, TA_L2 and TA_L3 located in the lower area LA, the second connection line DCL2 can be disposed.

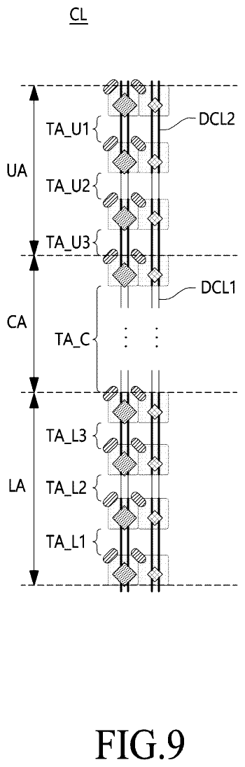

According to the example of FIG. 9, the second connection line DCL2 can be disposed in each of the first upper transmissive area TA_U1, the third upper transmissive area TA_U3, the first lower transmissive area TA_L1, and the third lower transmissive area TA_L3, whereas the first connection line DCL1 can be disposed in each of the second upper transmissive area TA_U2 and the second lower transmissive area TA_L2.

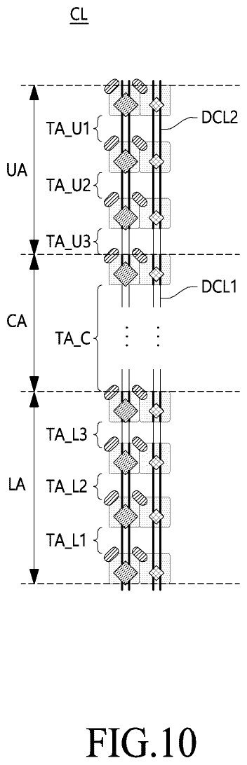

According to the example of FIG. 10, the second connection line DCL2 can be disposed in each of the first upper transmissive area TA_U1, the second upper transmissive area TA_U2, the first lower transmissive area TA_L1, and the second lower transmissive area TA_L2, whereas the first connection line DCL1 can be disposed in each of the third upper transmissive area TA_U3 and the third lower transmissive area TA_L3.

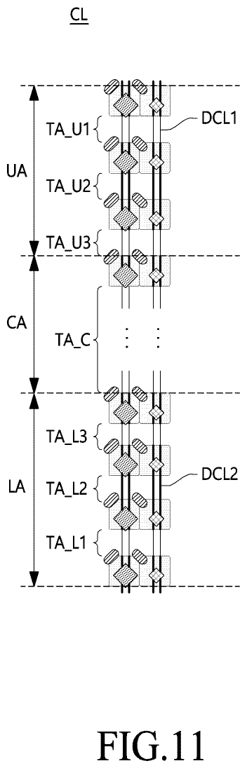

According to the example of FIG. 11, the second connection line DCL2 can be disposed in each of the second upper transmissive area TA_U2 and the second lower transmissive area TA_L2, whereas the first connection line DCL1 can be disposed in each of the first upper transmissive area TA_U1, the third upper transmissive area TA_U3, the first lower transmissive area TA_L1, and the third lower transmissive area TA_L3.

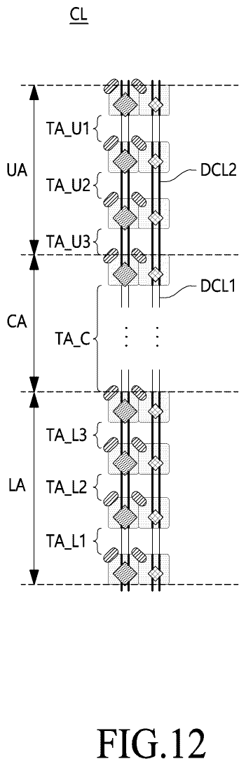

According to the example of FIG. 12, the second connection line DCL2 can be disposed in each of the second upper transmissive area TA_U2, the third upper transmissive area TA_U3, the second lower transmissive area TA_L2, and the third lower transmissive area TA_L3, whereas the first connection line DCL1 can be disposed in each of the first upper transmissive area TA_U1 and the first lower transmissive area TA_L1.

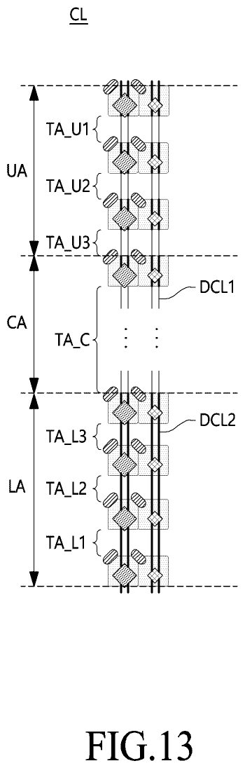

According to the example of FIG. 13, the first connection line DCL1 can be disposed in each of the first to third upper transmissive areas TA_U1, TA_U2, and TA_U3, whereas the second connection line DCL2 can be disposed in each of the first to third lower transmissive areas TA_L1, TA_L2, and TA_L3.

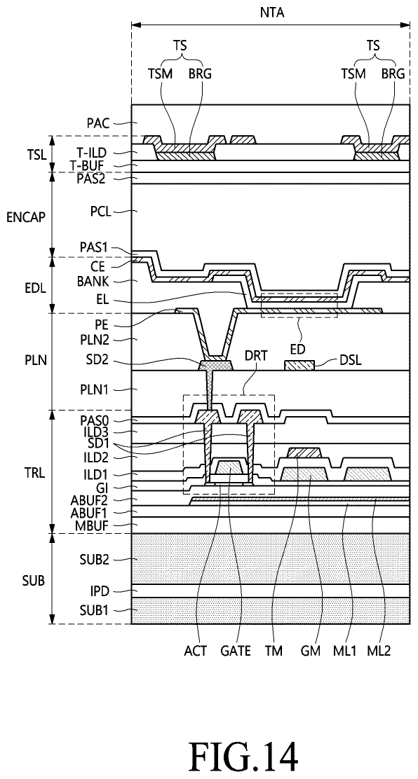

FIG. 14 to FIG. 18 are diagrams for illustrating implementation examples of the display device 100 according to embodiments of the present disclosure.

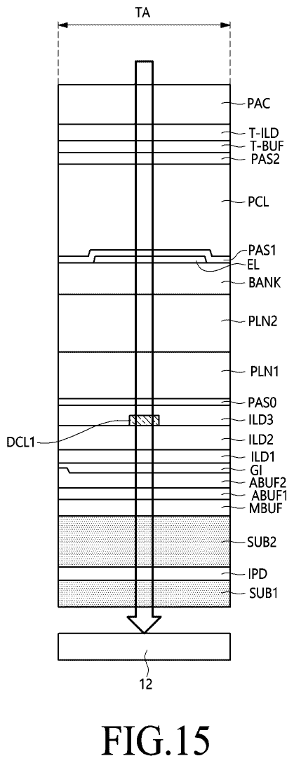

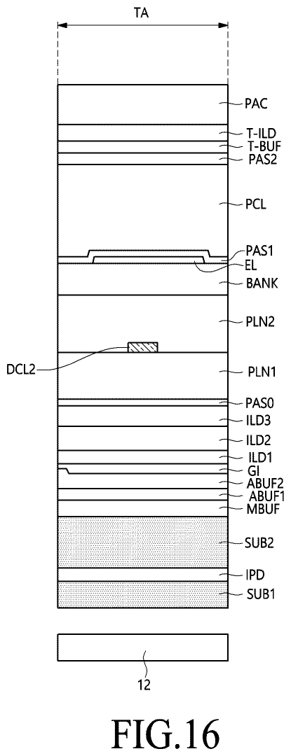

Specifically, FIG. 14 illustrates a cross-sectional view of a non-transmissive area NTA of the optical area OA included in the display device 100 according to embodiments of the present disclosure, and FIG. 15 and FIG. 16 illustrate cross-sectional views of the transmissive area TA of the optical area OA.

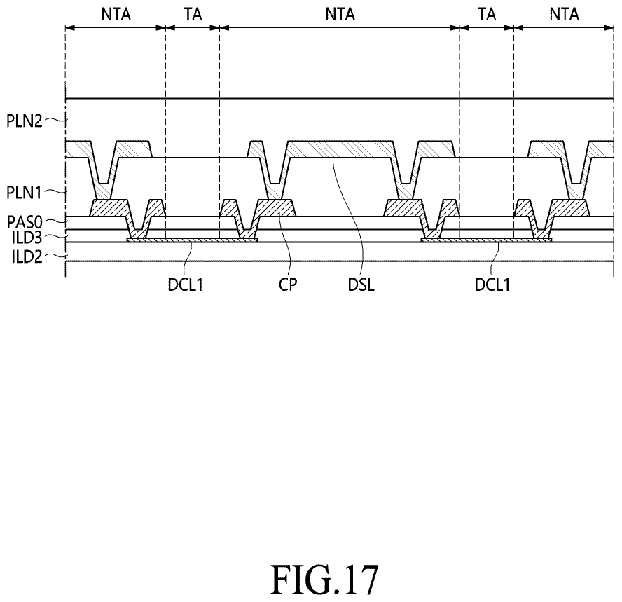

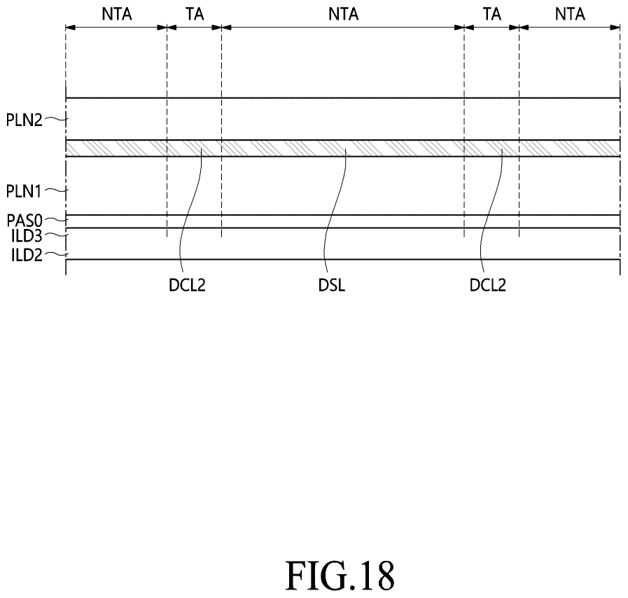

Additionally, FIG. 17 illustrates a cross-sectional view showing the connection relationship between the first connection line DCL1 and the data sub-line DSL when the data connection line disposed in the transmissive area TA is the first connection line DCL1. FIG. 18 illustrates a cross-sectional view showing the connection relationship between the second connection line DCL2 and the data sub-line DSL when the data connection line disposed in the transmissive area TA is the second connection line DCL2.

More specifically, FIG. 17 illustrates a cross-sectional view in which the first connection line DCL1 is disposed in at least one transmissive area TA adjacent to the non-transmissive area NTA including the first emission area, and FIG. 18 illustrates a cross-sectional view in which the second connection line DCL2 is disposed in at least one transmissive area TA adjacent to the non-transmissive area NTA including the first emission area.

Referring to FIG. 14 to FIG. 16, the display device 100 according to embodiments of the present disclosure can include a non-transmissive area NTA and a transmissive area TA within the optical area OA. The non-transmissive area NTA can include the first emission area EA1.

In the examples of FIG. 14 to FIG. 16, for the sake of explanation, the transmissive area TA of the optical area OA is illustrated as overlapping with the first optoelectronic device 11. However, the transmissive area TA of the optical area OA can also overlap with the second optoelectronic device 12.

Additionally, although the first optoelectronic device 11 is illustrated as overlapping with the transmissive area TA in the examples of FIG. 14 to FIG. 16, the first optoelectronic device 11 can also overlap with at least a portion of the non-transmissive area NTA included in the optical area OA.

The non-transmissive area NTA and the transmissive area TA can include a substrate SUB, a transistor layer TRL, a planarization layer PLN, a light-emitting device layer EDL, an encapsulation layer ENCAP, a touch sensor layer TSL, and a protective layer PAC.

First, referring to FIG. 14, the laminated structure of the non-transmissive area NTA will be described.

The substrate SUB can include a first substrate SUB1, an intermediate insulating layer IPD, and a second substrate SUB2. The intermediate insulating layer IPD can be located between the first substrate SUB1 and the second substrate SUB2. By forming the substrate SUB with the first substrate SUB1, the intermediate insulating layer IPD, and the second substrate SUB2, moisture infiltration can be prevented. For example, the first substrate SUB1 and the second substrate SUB2 can be polyimide (PI) substrates. The intermediate insulating layer IPD can include an inorganic material. For example, the intermediate insulating layer IPD can include silicon nitride (SiNx) or silicon oxide (SiOx).

The transistor layer TRL disposed on the substrate SUB can include various patterns (ACT, SD1, GATE) for forming transistors such as the driving transistor DRT, various insulating films (MBUF, ABUF1, ABUF2, GI, ILD1, ILD2, ILD3, PAS0), and various metal patterns (TM, GM, ML1, ML2).

According to embodiments, at least one additional insulating film can be further disposed between the second interlayer insulating film ILD2 and the third interlayer insulating film ILD3 and/or between the third interlayer insulating film ILD3 and the passivation layer PAS0.

Hereinafter, the laminated structure of the transistor layer TRL will be described in more detail.

A multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. Here, the first metal layer ML1 and the second metal layer ML2 can serve as a light shield.

A second active buffer layer ABUF2 can be disposed on the first metal layer ML1 and the second metal layer ML2, and an active layer ACT of the driving transistor DRT can be disposed on the second active buffer layer ABUF2.

A gate insulating film GI can be disposed covering the active layer ACT.

A gate electrode GATE of the driving transistor DRT can be disposed on the gate insulating film GI. In this case, at a position different from where the driving transistor DRT is formed, a gate material layer GM can be disposed on the gate insulating film GI along with the gate electrode GATE of the driving transistor DRT.

A first interlayer insulating film ILD1 can be disposed covering the gate electrode GATE and the gate material layer GM. A metal pattern TM can be disposed on the first interlayer insulating film ILD1. A second interlayer insulating film ILD2 can be disposed covering the metal pattern TM on the first interlayer insulating film ILD1.

A third interlayer insulating film ILD3 can be disposed on the second interlayer insulating film ILD2, and two first source-drain electrode patterns SD1 can be disposed on the third interlayer insulating film ILD3. Among the two first source-drain electrode patterns SD1, one can be the source node of the driving transistor DRT, and the other can be the drain node of the driving transistor DRT.

The two first source-drain electrode patterns SD1 can be connected to one side and the other side of the active layer ACT through contact holes of the third interlayer insulating film ILD3, the second interlayer insulating film ILD2, the first interlayer insulating film ILD1, and the gate insulating film GI. The portion of the active layer ACT overlapping the gate electrode GATE can be a channel region. Among the two first source-drain electrode patterns SD1, one can be connected to one side of the channel region in the active layer ACT, and the other can be connected to the other side of the channel region in the active layer ACT.

A passivation layer PAS0 can be disposed covering the two first source-drain electrode patterns SD1.

A planarization layer PLN can be disposed on the transistor layer TRL. The planarization layer PLN can include a first planarization layer PLN1 and a second planarization layer PLN2.

The first planarization layer PLN1 can be disposed on the passivation layer PAS0. A second source-drain electrode pattern SD2 can be disposed on the first planarization layer PLN1. The second source-drain electrode pattern SD2 can be connected to one of the two first source-drain electrode patterns SD1 (corresponding to the N2 node in FIG. 4) through a contact hole in the first planarization layer PLN1.

A data connection line DCL according to one embodiment of the present invention can be disposed above the first source-drain electrode pattern SD1 and the second source-drain electrode pattern SD2, and below the first planarization layer PLN1, for example, can be disposed between the source-drain electrode patterns (e.g., SD1 and SD2) and the planarization layer (PLN1).

A data connection line DCL according to another embodiment of the present invention can be disposed under the first source-drain electrode patterns SD1 and the second source-drain electrode patterns SD2, and can be disposed between the second interlayer insulating film ILD2 and the third interlayer insulating film ILD3.

A data sub-line DSL can be disposed on the first planarization layer PLN1.

The second planarization layer PLN2 can be disposed covering the second source-drain electrode pattern SD2 and the data sub-line DSL. A light-emitting device layer EDL can be positioned on the plurality of planarization layers, particularly the second planarization layer PLN2, and includes a plurality of light-emitting devices ED corresponding to each of the plurality of emission areas EA.

For example, the light-emitting device layer EDL can include a light-emitting device ED formed by a pixel electrode PE, an emission layer EL, and a common electrode CE. The emission layer EL can include an organic film.

The pixel electrode PE can be disposed on the second planarization layer PLN2, and the pixel electrode PE can be electrically connected to the second source-drain electrode pattern SD2 through a contact hole in the second planarization layer PLN2.

A bank BANK can be disposed covering the pixel electrode PE. The bank BANK can have an opening corresponding to the emission area of the sub-pixel SP. A portion of the pixel electrode PE can be exposed through the opening of the bank BANK. The emission layer EL can be disposed within and around the opening of the bank BANK. Accordingly, the emission layer EL can be disposed on the pixel electrode PE exposed through the opening of the bank BANK.

A common electrode CE can be disposed on the emission layer EL. For example, the common electrode CE can be a cathode electrode.

The encapsulation layer ENCAP can be disposed on the aforementioned light-emitting device layer EDL.

The encapsulation layer ENCAP can have a single-layer structure or a multi-layer structure. For example, as illustrated in FIG. 14, the encapsulation layer ENCAP can include a lower encapsulation layer PAS1, an intermediate encapsulation layer PCL, and an upper encapsulation layer PAS2.

However, the display device 100 according to embodiments of the present disclosure is not limited thereto and can include only the intermediate encapsulation layer PCL.

The lower encapsulation layer PAS1 and the upper encapsulation layer PAS2 can be inorganic films, and the intermediate encapsulation layer PCL can be an organic film or an inorganic film. The intermediate encapsulation layer PCL can function as a planarization layer.

The lower encapsulation layer PAS1 can be disposed on the common electrode CE and can be positioned closest to the light-emitting device ED. The lower encapsulation layer PAS1 can be formed of an inorganic insulating material that can be deposited at a low temperature. For example, the lower encapsulation layer PAS1 can be formed of silicon nitride SiNx, silicon oxide SiOx, silicon oxynitride SiON, or aluminum oxide Al₂O₃. Since the lower encapsulation layer PAS1 is deposited in a low-temperature environment, it can prevent the emission layer EL, which includes organic materials vulnerable to high temperatures, from being damaged during the deposition process.

The intermediate encapsulation layer PCL functions as a buffer to alleviate stress between layers caused by the bending of the display device 100 and can also enhance planarization performance. For example, the intermediate encapsulation layer PCL can be formed of an organic insulating material such as acrylic resin, epoxy resin, polyimide, polyethylene, or silicon oxycarbon SiOC. The intermediate encapsulation layer PCL can also be formed using an inkjet method.

For reference, in order to prevent the encapsulation layer ENCAP from collapsing, the display panel 110 can include at least one dam at the end point of the inclined surface of the encapsulation layer ENCAP or in the vicinity thereof. The at least one dam can be positioned at or near the boundary between the display area DA and the non-display area NDA.

The intermediate encapsulation layer PCL, which includes organic material, can be positioned only on the inner side of the first dam. For example, the intermediate encapsulation layer PCL may not be present on the upper portions of all the dams. Alternatively, the intermediate encapsulation layer PCL can be positioned on the upper portion of at least the first dam among the first dam and the second dam. In other words, the intermediate encapsulation layer PCL can extend only up to the upper portion of the first dam. Or, the intermediate encapsulation layer PCL can extend beyond the upper portion of the first dam and reach the upper portion of the second dam.

The upper encapsulation layer PAS2 can be formed on the substrate SUB, where the intermediate encapsulation layer PCL is formed, to cover the upper and side surfaces of both the intermediate encapsulation layer PCL and the lower encapsulation layer PAS1. The upper encapsulation layer PAS2 can minimize or block the infiltration of external moisture or oxygen into the lower encapsulation layer PAS1 and the intermediate encapsulation layer PCL. For example, the upper encapsulation layer PAS2 can be formed of an inorganic insulating material such as silicon nitride (SiNx), silicon oxide (SiOx), silicon oxynitride (SiON), or aluminum oxide (Al₂O₃).

A touch sensor layer TSL can be disposed on the aforementioned encapsulation layer ENCAP.

A touch buffer layer T-BUF can be disposed on the encapsulation layer ENCAP, and a touch sensor TS can be disposed on the touch buffer layer T-BUF. The touch sensor TS can include touch sensor metals TSM located on different layers and bridge metals BRG. A touch interlayer insulating film T-ILD can be disposed between the touch sensor metals TSM and the bridge metals BRG.

For example, the touch sensor metals TSM can include a first touch sensor metal TSM, a second touch sensor metal TSM, and a third touch sensor metal TSM arranged adjacent to each other. The first touch sensor metal TSM and the second touch sensor metal TSM need to be electrically connected, but if a third touch sensor metal TSM is present between them, they can be electrically connected through a bridge metal BRG positioned on a different layer. The bridge metal BRG can be insulated from the third touch sensor metal TSM by the touch interlayer insulating film T-ILD.

During the formation of the touch sensor layer TSL, processing chemicals (such as developer or etchant) or external moisture can be generated. By placing the touch buffer layer T-BUF and then forming the touch sensor layer TSL on the top of it, the penetration of processing chemicals or moisture into the emission layer EL, which contains organic materials, can be prevented during the manufacturing process of the touch sensor layer TSL. Accordingly, the touch buffer layer T-BUF can prevent damage to the emission layer EL, which is vulnerable to processing chemicals or moisture.

The touch buffer layer T-BUF is formed of an organic insulating material that has a low dielectric constant of 1 to 3 and can be formed at a low temperature (e.g., 100° C. or lower), to prevent damage to the emission layer EL, which contains organic materials that are vulnerable to high temperatures. For example, the touch buffer layer T-BUF can be made of an acrylic-based material, an epoxy-based material, or a siloxane-based material. When the display device 100 is bent, the encapsulation layer ENCAP can be damaged, and the touch sensor metals located on the touch buffer layer T-BUF can break. Even if the display device 100 bends, the touch buffer layer T-BUF, which has planarization properties due to its organic insulating material, can prevent damage to the encapsulation layer ENCAP and/or the breakage of the metals (TSM, BRG) constituting the touch sensor TS.

A protective layer PAC can be disposed over the touch sensor TS. The protective layer PAC can be an organic insulating film.

According to the example in FIG. 15, in one of the plurality of transmissive areas TA, the first connection line DCL1 can be disposed on the second interlayer insulating film ILD2, and the third interlayer insulating film ILD3 can be disposed over the first connection line DCL1, covering it while being positioned on the second interlayer insulating film ILD2.

According to the example in FIG. 16, in another one of the plurality of transmissive areas TA, the second connection line DCL2 can be disposed on the first planarization layer PLN1, and the second planarization layer PLN2 can be disposed over the second connection line DCL2, covering it while being positioned on the first planarization layer PLN1.

Referring to FIG. 17, the data sub-line DSL overlapping the first emission area EA1 within at least one non-transmissive area NTA can be disposed on the first planarization layer PLN1, and the first connection line DCL1 overlapping at least one transmissive area TA adjacent to at least one non-transmissive area NTA can be disposed on any one of the plurality of interlayer insulating films, e.g., the second interlayer insulating film ILD2.

According to the example in FIG. 17, the data sub-line DSL and the first connection line DCL1, which are disposed on different layers, can be electrically connected through a connection pattern CP disposed on the passivation layer PAS0.

Referring to FIG. 18, the data sub-line DSL overlapping the first emission area EA1 in at least one non-transmissive area NTA and the second connection line DCL2 overlapping at least one transmissive area TA adjacent to at least one non-transmissive area NTA can be disposed on the first planarization layer PLN1.

For example, the data sub-line DSL and the second connection line DCL2 can be formed on the same layer, specifically on any one of the plurality of planarization layers, e.g., the first planarization layer PLN1, especially in at least one of the plurality of transmissive areas TA, through a single manufacturing process using the same material.

A brief discussion of the embodiments of the present disclosure described above is as follows.

A display device according to embodiments of the present disclosure can comprise: a display panel including an optical area having a plurality of transmissive areas and a plurality of first emission areas, a general area disposed outside the optical area and having a plurality of second emission areas, and a plurality of data connection lines arranged in a first direction in at least one of the plurality of transmissive areas; and an optoelectronic device disposed below the display panel and overlapping the optical area. The plurality of data connection lines can include at least one first connection line arranged in a first area and a second area of the optical area, and at least one second connection line arranged in the first area and having a lower resistance than the first connection line.

The second area can be located on each of the first and second sides of the first area.

The first area can be divided into an upper area, an intermediate area, and a lower area, and at least one second connection line can be arranged in at least one of the upper area and the lower area.

At least one first connection line can be arranged in the intermediate area.

At least one first connection line can be arranged in at least one of the upper area and the lower area.

At least one data connection line arranged in the first area among the plurality of data connection lines and at least one data connection line arranged in the second area among the plurality of data connection lines can have different wiring widths.

At least one data connection line arranged in the first area among the plurality of data connection lines can have a larger wiring width than at least one data connection line arranged in the second area among the plurality of data connection lines.

At least one data connection line arranged in the first area among the plurality of data connection lines and at least one data connection line arranged in the second area among the plurality of data connection lines can have different wiring lengths.

At least one data connection line arranged in the second area among the plurality of data connection lines can be lines with curves or angular turns, wherein the lines with curves or angular turns can include a zigzag pattern. The wirings disposed in the second area, which are lines with curves or angular turns, can include any one of a power line, a power connection line, a low potential line, the data connection line, and a data sub-line.

The display panel can include a plurality of data sub-lines disposed in the first direction in the plurality of first emission areas and arranged in a different layer from at least one first connection line, and at least one connection pattern that electrically connects at least one of the plurality of data sub-lines to a corresponding line among at least one first connection line.

The plurality of data sub-lines can have a lower resistance than the first connection line.

At least one first connection line can be a high-transmittance line.

The display panel can further include a substrate, a transistor layer disposed on the substrate and including at least one transistor and a plurality of interlayer insulating films, and a plurality of planarization layers disposed on the transistor layer.

The plurality of data sub-lines can be disposed on any one of the plurality of planarization layers.

At least one first connection line can be disposed on any one of the plurality of interlayer insulating films.

At least one second connection line can be disposed on any one of the plurality of planarization layers.

A display device according to embodiments of the present disclosure can comprise: a substrate including a plurality of transmissive areas and a plurality of emission areas; a transistor layer disposed on the substrate and including at least one transistor and a plurality of interlayer insulating films; a plurality of planarization layers disposed on the transistor layer; a plurality of data sub-lines disposed on any one of the plurality of planarization layers in the plurality of emission areas, and electrically connected to at least one of at least one first connection line and at least one second connection line; and an light-emitting device layer disposed on the plurality of planarization layers and including a plurality of light-emitting devices corresponding to each of the plurality of emission areas.

At least one first connection line can be disposed on any one of the plurality of interlayer insulating films, in at least one of the plurality of transmissive areas.

At least one second connection line can be disposed on any one of the plurality of planarization layers, in at least one of the plurality of transmissive areas.

A display device according to embodiments of the present disclosure can comprise: a display panel including an optical area having a plurality of transmissive areas and a plurality of first emission areas, a general area disposed outside the optical area and having a plurality of second emission areas, and a plurality of data connection lines disposed in a first direction in at least one of the plurality of transmissive areas; and an optoelectronic device disposed below the display panel and overlapping the optical area, wherein the plurality of data connection lines includes at least one first connection line disposed in a first area and a second area of the optical area, and at least one second connection line disposed in the first area, and wherein at least one of the plurality of data connection lines disposed in the second area can be lines with curves or angular turns.

A display device according to embodiments of the present disclosure can comprise: a substrate, which includes an optical area including a plurality of transmissive areas and a plurality of emission areas; a transistor layer disposed on the substrate and including at least one transistor and a plurality of interlayer insulating films; a plurality of planarization layers disposed on the transistor layer; a plurality of data sub-lines disposed on any one of the plurality of planarization layers in the plurality of emission areas and electrically connected to at least one of at least one first connection line and at least one second connection line of a plurality of data connection lines; and a light-emitting device layer disposed on the plurality of planarization layers and including a plurality of light-emitting devices corresponding to each of the plurality of emission areas, wherein the optical area includes a first area and a second area, and at least one of the plurality of data sub-lines disposed in the second area can be lines with curves or angular turns.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a display panel including an optical area having a plurality of transmissive areas and a plurality of first emission areas, a general area disposed outside of the optical area and having a plurality of second emission areas, and a plurality of data connection lines disposed in a first direction in at least one of the plurality of transmissive areas; and
an optoelectronic device disposed below the display panel and overlapping the optical area,
wherein the plurality of data connection lines includes at least one first connection line disposed in a first area and a second area of the optical area, and at least one second connection line disposed in the first area and having a lower resistance than the at least one first connection line.

2. The display device of claim 1, wherein the second area of the optical area is an area located at each of a first side and a second side of the first area of the optical area.

3. The display device of claim 1, wherein the first area of the optical area is divided into an upper area, an intermediate area, and a lower area, and the at least one second connection line is disposed in at least one of the upper area and the lower area.

4. The display device of claim 3, wherein the at least one first connection line is disposed in the intermediate area of the first area of the optical area.

5. The display device of claim 3, wherein the at least one first connection line is disposed in at least one of the upper area and the lower area of the first area of the optical area.

6. The display device of claim 1, wherein at least one of the plurality of data connection lines disposed in the first area of the otpical area and at least one of the plurality of data connection lines disposed in the second area of the otpical area have different wiring widths.

7. The display device of claim 1, wherein at least one of the plurality of data connection lines disposed in the first area of the otpical area has a larger wiring width than at least one of the plurality of data connection lines disposed in the second area of the otpical area.

8. The display device of claim 1, wherein at least one of the plurality of data connection lines disposed in the first area of the otpical area and at least one of the plurality of data connection lines disposed in the second area of the otpical area have different wiring lengths.

9. The display device of claim 1, wherein at least one of the plurality of data connection lines disposed in the second area of the otpical area includes lines with curves or angular turns.

10. The display device of claim 9, wherein the lines with curves or angular turns include a zigzag pattern.

11. The display device of claim 1, wherein at least one of the plurality of data connection lines is disposed between a planarization layer and a source-drain electrode pattern.

12. The display device of claim 1, wherein at least one of the plurality of data connection lines is disposed under a source-drain electrode pattern.

13. The display device of claim 12, wherein the at least one of the plurality of data connection lines is disposed between a plurality of interlayer insulating films.

14. The display device of claim 1, wherein the display panel comprises:
a plurality of data sub-lines disposed in the first direction in the plurality of first emission areas and disposed in a different layer from the at least one first connection line; and
at least one connection pattern electrically connecting at least one of the plurality of data sub-lines to a corresponding line among the at least one first connection line.

15. The display device of claim 14, wherein the plurality of data sub-lines has a lower resistance than the at least one first connection line.

16. The display device of claim 1, wherein the at least one first connection line has a high light transmittance.

17. The display device of claim 14, wherein the display panel comprises:
a substrate;
a transistor layer disposed on the substrate and including at least one transistor and a plurality of interlayer insulating films; and
a plurality of planarization layers disposed on the transistor layer,
wherein the plurality of data sub-lines is disposed on any one of the plurality of planarization layers.

18. The display device of claim 17, wherein the at least one first connection line is disposed on any one of the plurality of interlayer insulating films.

19. The display device of claim 17, wherein the at least one second connection line is disposed on any one of the plurality of planarization layers.

20. A display device comprising:
a substrate including a plurality of transmissive areas and a plurality of emission areas;
a transistor layer disposed on the substrate and including at least one transistor and a plurality of interlayer insulating films;
a plurality of planarization layers disposed on the transistor layer;
a plurality of data sub-lines disposed on any one of the plurality of planarization layers in the plurality of emission areas and electrically connected to at least one of at least one first connection line and at least one second connection line of a plurality of data connection lines; and
a light-emitting device layer disposed on the plurality of planarization layers and including a plurality of light-emitting devices corresponding to the plurality of emission areas.
